(19) United States
(12) Patent Application Publication
(10) Pub. No.: US 2006/0138643 A1
(43) Pub. Date: Jun. 29, 2006

(54) One step capillary underfill integration for semiconductor packages

(76) Inventors: Daoqiang Lu, Chandler, AZ (US); Tian-An Chen, Phoenix, AZ (US); Mike Garner, Pleasanton, CA (US)

Correspondence Address: INTEL/BLAKELY, 12400 WILSHIRE BOULEVARD, SEVENTH FLOOR, LOS ANGELES, CA, 90025-1030, US

(21) Appl. No.: 11/024,553

(22) Filed: Dec. 28, 2004

(51) Int. Cl. H01L 21/48; H01L 23/52

(52) U.S. Cl. 257/706; 438/125; 257/707; 257/712; 438/122

(57) ABSTRACT

The present invention relates to a semiconductor package containing a package substrate, integrated heat spreader, and semiconductor die. An underfill material is embedded in the semiconductor package serving both as underfill and sealant.

### BACKGROUND

1. Field

The present invention relates to the field of semiconductor packaging, specifically a semiconductor package comprising a dual purpose underfill.

2. Description of Related Art

Semiconductor packaging involves connecting a semiconductor die to a motherboard without compromising electrical, thermal, and mechanical performance. As semiconductor devices become more complex, with transistor count exceeding 100 million per die, semiconductor packaging becomes more challenging.

Flip chip packaging, a conventional semiconductor packaging scheme, utilizes an underfill material to compensate for differences in thermal expansion rates of semiconductor die electrical contacts and the package substrate. A successful underfill completely encapsulates the bottom side of die with an even meniscus on all sides, void of air entrapments. Underfill material is usually dispensed at the edges of the semiconductor die. Some conventional thin-die packages present underfill dispensing challenges because the semiconductor die edges are over covered by the heat sink.

### BRIEF DESCRIPTION OF THE DRAWINGS

FIG. 1 is a cross-sectional view illustration of semiconductor package 100 according to an embodiment of the present invention.

FIG. 2A is an illustration of the thickness of a semiconductor wafer pre and post thinning.

FIG. 2B is an illustration of a process for sputtering metal on the backside of a semiconductor wafer and integrated heat spreader for subsequent soldering.

FIG. 2C is a top view illustration of a semiconductor wafer displaying a plurality of fabricated semiconductor die.

FIG. 2D is an illustration of a plurality of semiconductor die after partitioning a semiconductor wafer.

FIG. 2E is an illustration of a semiconductor die attached to an integrated heat spreader post deposition of composite metal films for subsequent soldering.

FIG. 2F is an illustration of a semiconductor die bonded to an integrated heat spreader forming a composite.

FIG. 2G is an illustration of a semiconductor die/integrated heat spreader composite bonded to a package substrate.

FIG. 2H is an illustration of an underfill dispensed adjacent to a package substrate by a dispensing needle.

FIGS. 2I-2K are illustrations of the progression of an underfill between an integrated heat spreader and package substrate post dispensement.

FIG. 2L is an illustration of a cured underfill between an integrated heat spreader and package substrate post dispensement.

### DETAILED DESCRIPTION OF THE PRESENT INVENTION

The present invention is a method of integrating an underfill in a semiconductor package comprising a substrate, thinned semiconductor die, and integrated heat spreader by a single-step, capillary underfill integration process. The underfill material used in the present invention serves both as an underfill and a sealant for the semiconductor package. In the present invention, the underfill material is applied such that it lies between the integrated heat spreader and the substrate and between the semiconductor die and the substrate. The present invention is ideal for applying an underfill to thin semiconductor die packages, such as a thin di-thin thermal interface material (TIM) (TDTT) package. By integrating an underfill in a semiconductor package according to the present invention, a more reliable thin die semiconductor package, single-step underfill integration method, sealant step elimination, and dual purpose underfill may be obtained.

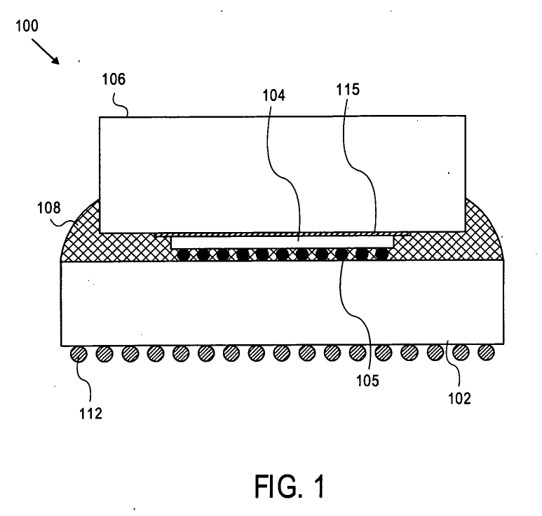

FIG. 1 is an illustration of a semiconductor package 100 in accordance with an embodiment of the present invention. Semiconductor package 100 comprises package substrate 102, semiconductor die 104, integrated heat spreader 106, and underfill 108 as shown in FIG. 1. A thermal interface material 115, such as solder, connects the die 104 and integrated heat spreader 106. Underfill 108 is formed between semiconductor die 104 and package substrate 102 as well as between integrated heat spreader 106 and package substrate 102. In an embodiment, underfill 108 serves to increase the reliability of the semiconductor package by reducing thermal and mechanical induced stress, improve fatigue life, seal out moisture, and provide a thermal conductive path. Underfill serves a dual purpose of an underfill material and a sealant. Underfill 108 serves as a sealant in semiconductor package 100, by encapsulating the region between integrated heat spreader 106 and package substrate 102 as illustrated in FIG. 1.

In an embodiment, underfill 108 flows, by capillary action, between integrated heat spreader 106 and package substrate 102 to encompass the surface area of integrated heat spreader 106 with no appreciable voiding. In an embodiment, a highly flowable underfill is used with a viscosity less than 100 poise, at room temperature. For example Nemics Corporation manufactures underfills suitable for use in embodiments of the present invention. In an embodiment, Nemics underfill product U8434-29 is used. U8434-29 has a viscosity of 12 Pa·s (at 25° C.) and also features curing condition of 165° C./1 h, 100 second gel time, 150 T_{g}, 55 C.T.E (ppm), and purity <10 ppm. In another embodiment Nemics underfill product U8444-20 is used, which features a viscosity of 9 (at 25° C.), curing condition of 165° C./1 h, 900 sec. gel time, 100 T_{g}, 45 C.T.E. (ppm), and purity <10 ppm. In yet another embodiment, U8410-30 is used, which features a viscosity of 7 Pa·s (at 25° C.), curing condition of 165° C./1 h, 900 sec gel time, 110 T_{g}, 45 C.T.E. (ppm), and purity <10 ppm. In an embodiment, underfill 108 comprises a filler, such as silica, which features a low coefficient of thermal expansion. Silica filler is preferred in the underfill, but not required. Nemics underfill products U8434-29, U8444-20, and U8410-30 also feature silica fillers with 40% filler content and filler size less than 0.6 micrometers.

Semiconductor die 104 may be manufactured to a thickness which allows capillary underfill integration according to an embodiment of the present invention. In an embodiment, semiconductor die 104 is reduced in thickness after process fabrication, but before singulated from a parent wafer. For example, the thickness of semiconductor die 104 before thinning is approximately 750 microns. After thinning, the thickness of semiconductor 104 is reduced to a thickness less than 125 microns to improve thermal conductivity and achieve flow of underfill 108 between semiconductor die 104 and package substrate 102 by capillary action.

In an embodiment, the surface area of semiconductor die 104 is significantly smaller than the surface area of integrated heat spreader 106. For example, a semiconductor package may feature an integrated heat spreader with a surface area of 30×30 mm² and a semiconductor die with a surface area of 10×10 mm². The size differential helps prevent warping of semiconductor 104 from mismatched coefficient of thermal expansions (CTE) between semiconductor 104 and integrated heat spreader 106.

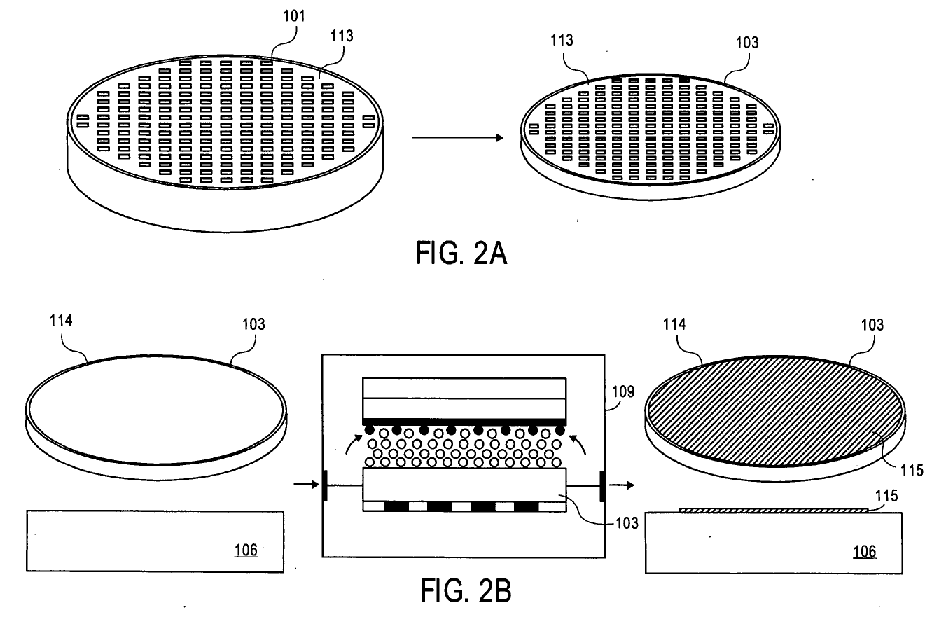

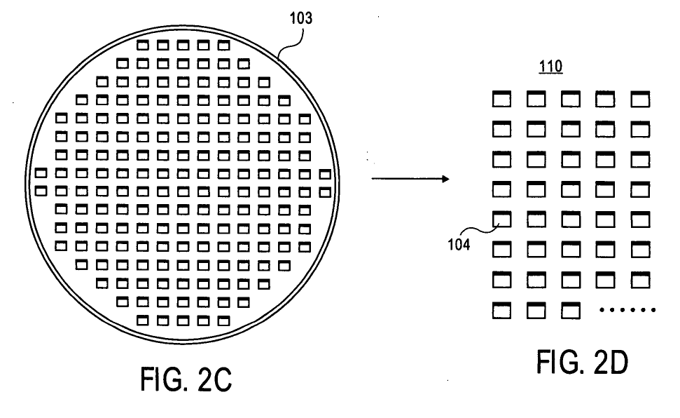

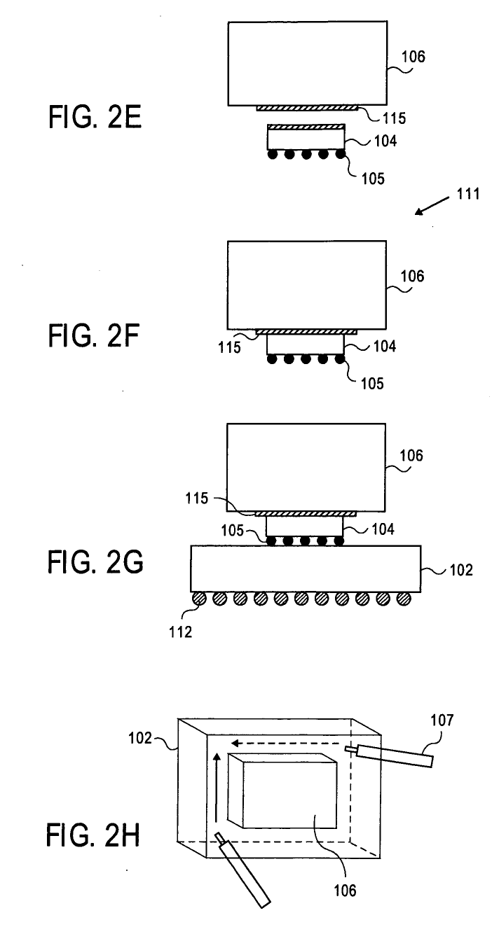

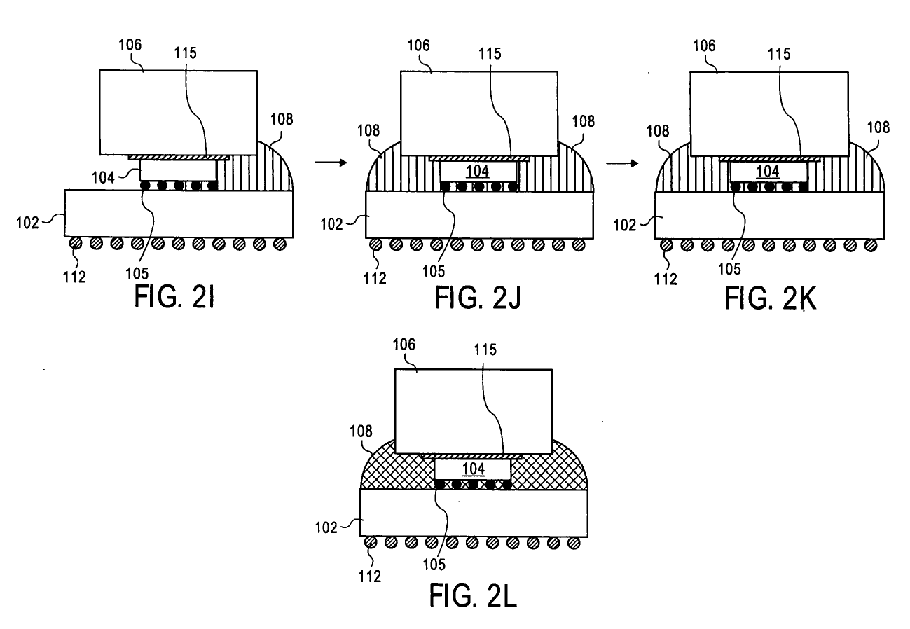

In an embodiment, the semiconductor package includes an integrated heat spreader 106, which typically serves to distribute heat from semiconductor die 104 over a larger surface area to increase the thermal management of semiconductor package 100. In an embodiment, integrated heat spreader 106 is made from copper, but other materials may be used. In the present invention, integrated heat spreader 106 is attached to semiconductor die 104 by a thermal interface material 115. In an embodiment, integrated heat spreader 106 is attached to semiconductor die 104 through a soldering process. In an embodiment, composite metal film Ti/Ni/Au is deposited on the backside 114 of semiconductor wafer 103 and composite metal film Ni/Au/Sn may be deposited on integrated heat spreader 106 as illustrated in FIG. 2B to form the thermal interface material 115. In another embodiment, a composite metal film Ti/Ni/Au/Sn may be deposited on the backside 114 of semiconductor die 104 and composite metal film Ni/Au may be deposited on integrated heat spreader 106. In both examples, Au/Sn is used as the solder. In an embodiment of the present invention, the thermal interface material 115 has a thickness between 3-75 microns. Attaching heat spreader 106 and semiconductor 104 forms composite 111, which has a CTE that closely matches the CTE of package substrate 102. In an embodiment, semiconductor die 104 is made thin enough such that the CTE of semiconductor die 104 is negligible in comparison to the CTE of integrated heat spreader 106 to avoid warping and/or cracking of semiconductor die 104 during power or temperature cycling.

In an embodiment, semiconductor package 100 includes package substrate 102, which typically is used to attach semiconductor package 100 to a motherboard and/or electrically couple semiconductor die 104 to other devices. In an embodiment, package substrate 102 is made from an organic material such as a printed circuit board (PCB), but may be made from inorganic materials such as ceramics. Package substrate 102 is attached to composite 111 by electrical contacts 105. Electrical contacts 105 may be comprised of PbSn, copper, or any material which enables electrical connectivity between package substrate 102 and composite 111. Electrical contacts 105 may be formed by any suitable technique. In an embodiment, electrical contacts are comprised of PbSn and are formed by a Control Collapse Chip Connect (C4) process. In an embodiment, package substrate 102 is attached to composite 111 via flip-chip processing. The distance between package substrate 102 and the semiconductor die 104 is manufactured such that underfill 108 flows by capillary action. For example, the distance between package substrate 102 and the semiconductor substrate portion of composite 111 is less than 150 microns in an embodiment of the present invention. Preferably, the distance between package substrate 102 and the semiconductor die 104 portion of composite 111 should be less than 75 microns to maximize underfill 108 flows via capillary action.

In an embodiment, the semiconductor package may be manufactured by any suitable process such that an underfill 108 may be integrated into semiconductor package 100. In an embodiment of the present invention, semiconductor package 100 is formed by a process, as illustrated in FIGS. 2A-2L, comprising thinning semiconductor wafer 101; depositing metal on the backside of thinned semiconductor wafer 103; singulating thinned semiconductor wafer 103 into plurality of semiconductor die 110; attaching semiconductor die 104 to integrated heat spreader 106; composite 111 to package substrate 102; applying underfill 108 to semiconductor package 100 to serve as an underfill and a sealant.

To manufacture semiconductor package 100 according to an embodiment as illustrated in FIG. 2A, semiconductor wafer 101 is thinned. In an embodiment, the thickness of semiconductor wafer 101 is approximately 750 microns prior to thinning. Semiconductor wafer 101 may be thinned by any suitable method such as, but not limited to mechanical grinding and chemical-mechanical polishing. After thinning, the thickness of semiconductor wafer 101 is such that the CTE of semiconductor die 104 is negligible in comparison to the CTE of integrated heat spreader 106 to avoid warping or cracking of semiconductor die 104 during power and/or temperature cycling. In an embodiment, the thickness of semiconductor die 104 after thinning is less than or equal to 125 microns. In FIG. 2A, semiconductor wafer 101 is shown after the thinning process as thinned semiconductor wafer 103. Thinning semiconductor wafer 101 translates into a thinned semiconductor die, which provides greater heat transfer conductivity through semiconductor die 104.

Next, composite metal film 115 is deposited on the backside of thinned semiconductor wafer 103 and integrated heat spreader 106 to enable soldering. In an embodiment of the present invention, Ti/Ni/Au and Ni/Au/Sn are composite metal films 115 which may deposited on thinned semiconductor wafer 103 and integrated heat spreader 106 respectively, for soldering. In another embodiment, Ti/Ni/Au/Sn and Ni/Au may be deposited on thinned semiconductor wafer 103 and integrated heat spreader 106 respectively for soldering. In an embodiment, composite metal film 115 may be deposited on the backside 114 of thinned semiconductor wafer 103 in sputter tool 109 as illustrated in FIG. 2B. However, other methods may be used for metallization of integrated heat spreader 106 and thinned semiconductor wafer 103.

Next as shown in FIG. 2D, thinned semiconductor wafer 103 is singulated into plurality of thinned semiconductor die 110. Semiconductor wafer 103 may be singulated by any suitable method such as, but not limited to sawing, laser cutting, or dicing. In FIG. 2C, an illustration of the top view of thinned semiconductor wafer 103 is shown prior to singulation. After singulation, thinned semiconductor wafer 103 is partitioned into plurality of thinned semiconductor die 110 as illustrated in FIG. 2D. Semiconductor die 104 is one of such thinned, partitioned die and will subsequently be attached to integrated heat spreader 106.

Next, semiconductor die 104 is attached to integrated heat spreader 106 after composite metal film 115 is deposited to enable soldering as illustrated in FIG. 2E. Next, semiconductor die 104 and integrated heat spreader 106 are soldered forming composite 111 as illustrated in FIG. 2F.

After attaching semiconductor die 104 to integrated heat spreader 106, composite 111 is attached to package substrate 102 as illustrated in FIG. 2G by a conventional flip-chip method. Semiconductor package 100 is manufactured such that the composite 111 is aligned on top of package substrate 102. Subsequently, electrical contacts 105 of semiconductor die 104 are reflowed to form solder joints, thereby adjoining composite 111 to package substrate 102. In an embodiment, a flux is dispensed on package substrate 102 prior to attaching to composite 111. The flux dispensed on package substrate 102 may be a clean or no-clean flux. If a clean flux is used then a de-flux process is used to remove before underfill 108 is dispensed. If a no-clean flux is used, no deflux step is required.

Next, underfill 108 is dispensed on package substrate 102 as illustrated in FIG. 2H. In an embodiment, underfill 108 is dispensed on one side of package substrate 102 such that underfill 108 encapsulates region between package substrate 102 and integrated heat spreader 106. In an embodiment, underfill 108 is dispensed on two adjacent sides of package substrate 102 to ensure underfill 108 encapsulates the region between package substrate 102 and integrated heat spreader 106. In an embodiment, dispensing underfill 108 on package substrate 102 is repeated multiple times. In an embodiment, underfill 108 is dispensed on package substrate 102 five times to fill the volume between package substrate 102 and integrated heat spreader 106, with minimal voiding. FIGS. 2I-2K are illustrations of the progression of underfill 108 flowing to fill the surface area of integrated heat spreader 106 through semiconductor package 100. In an embodiment, semiconductor package 100 is pre-heated before underfill 108 is dispensed on package substrate 102. In an alternate embodiment, underfill 108 is dispensed from a dispensing needle, whereby the dispensing needle is pre-heated. For example, a dispensing needle used to dispense underfill 108 according to an embodiment of the present invention is pre-heated to a temperature in the range 60-80° C. In an embodiment, once dispensed, underfill 108 is cured as illustrated in FIG. 2L. For example, underfill 108 is cured at 160° C. for two hours.

1. A semiconductor package comprising:
a substrate;
an integrated heat spreader;
a semiconductor die attached to said integrated heat spreader forming a composite, wherein said semiconductor die is bonded to said substrate;
an underfill material between said semiconductor die and
said substrate and between said integrated heat spreader and said substrate.

2. The semiconductor package of claim 1, wherein the thickness of said semiconductor die is less than 750 microns.

3. The semiconductor package of claim 2, wherein the thickness of said semiconductor die is less than or equal to 125 microns.

4. The semiconductor package of claim 1, wherein said integrated heat spreader comprises copper.

5. The semiconductor package of claim 1, wherein said semiconductor die is flip-chip bonded to said substrate.

6. The semiconductor package of claim 1, wherein said integrated heat spreader has a first surface area and said semiconductor die has a second surface area; wherein said first surface area is greater than said second surface area.

7. The semiconductor package of claim 1, wherein said composite has a coefficient of thermal expansion closely matching that of said substrate.

8. The semiconductor package of claim 1, wherein said substrate comprises an organic material.

9. The semiconductor package of claim 1, wherein said semiconductor die is separated from said substrate by a distance less than 150 microns.

10. The semiconductor package of claim 1, wherein viscosity of said underfill is less than 100 poise at room temperature.

11. The semiconductor package of claim 1, wherein underfill has a filler comprising silica.

12. A method of forming a semiconductor package comprising:
attaching a semiconductor die to an integrated heat spreader;
attaching said semiconductor die to a substrate;
applying an underfill material to said substrate, wherein said underfill material is in direct contact with said semiconductor die and said integrated heat spreader.

13. The method of claim 12, wherein said semiconductor die is attached to said integrated heat spreader prior to attaching to said substrate.

14. The method of claim 12, wherein said attaching said semiconductor die to said integrated heat spreader comprises:
depositing metal on backside of said semiconductor die;
depositing metal on one side of said integrated heat spreader;
soldering said semiconductor die to said integrated heat spreader.

15. The method of claim 14, wherein said metal comprises a Ti, Ni, Au alloy.

16. The method of claim 14, wherein said metal is a Titanium, Nickel, Gold, Tin alloy.

17. A method of applying underfill material comprising:
attaching a semiconductor die to an integrated heat spreader and a substrate to form a semiconductor package;
dispensing an underfill material at the perimeter of two adjacent sides of an integrated heat spreader, wherein said underfill material flows between said integrated heat spreader and said substrate and flows between said integrated heat spreader and said semiconductor die to fill said integrated heat spreader area through capillary action; and
providing mechanical stability to said semiconductor package by directly contacting said underfill material to said substrate, said integrated heat spreader, and
said semiconductor die.

18. The method of claim 17, further comprising
repeating said dispensing multiple times to fill the entire surface of said integrated heat spreader.

19. The method of claim 18, wherein said dispensing is repeated five times.

20. The method of claim 17, further comprising curing said underfill material.

21. The method of claim 20, wherein said underfill material is cured at 160 degrees Celsius.

22. A method of forming a semiconductor package comprising:
thinning a semiconductor wafer to form a thinned semiconductor wafer; depositing metal on backside of said thinned semiconductor wafer;
partitioning semiconductor wafer into a plurality of die;
soldering one of said plurality die to an integrated heat spreader to form a composite;
dispensing a flux material to a substrate;
aligning said die and said integrated heat spreader composite on said substrate;
soldering said composite to said substrate to form solder joints;
wherein said soldering forms a semiconductor package comprising said die, said integrated heat spreader, and said substrate;
pre-heating said semiconductor package;
dispensing an underfill material at the perimeter of two adjacent sides of an integrated heat spreader and perpendicular to the substrate, wherein said underfill material flows between said integrated heat spreader and substrate and flows between said integrated heat spreader and semiconductor die to fill said integrated heat spreader area through capillary action and
providing mechanical stability to said semiconductor package by directly contacting said underfill material to said substrate, said integrated heat spreader, and said semiconductor die.

23. The method of claim 22, further comprising:
repeating dispensing process five times to fill the entire surface area of said integrated heat spreader.

24. The method of claim 22, further comprising: curing said underfill material.

25. The method of claim 22, wherein said substrate contains solder bumps.

26. The method of claim 22, wherein said dispensing proceeds from a dispensing needle.

27. The method of claim 26, wherein said dispensing needle is pre-heated to a temperature below the cure temperature of said underfill.

28. The method of claim 27, wherein said dispensing needle is pre-heated to a temperature in the range of 60-80 degrees Celsius.

29. The method of claim 24, wherein said curing of said underfill occurs in the range 1-3 hours.
